(19) United States
(12) Patent Application Publication
(10) Pub. No.: US 2008/0142803 A1
(43) Pub. Date: Jun. 19, 2008

(54) Display device and manufacturing method thereof

(76) Inventors: Takuo Kaitoh, Mobara (JP); Eiji Oue, Mobara (JP)

Correspondence Address: REED SMITH LLP, Suite 1400, 3110 Fairview Park Drive, Falls Church, VA, 22042, US

(21) Appl. No.: 12/000,403

(22) Filed: Dec. 12, 2007

(30) Foreign Application Priority Data
Dec. 18, 2006 (JP) 2006-339462

(51) Int. Cl. H01L 29/04; H01L 21/336

(52) U.S. Cl. 257/59; 438/164; 257/E21.413; 257/E29.003

(57) ABSTRACT

With the present invention, it is possible to provide a high quality image display by suppressing such faults as malfunction of a circuit or leakage of a current due to hump caused by the characteristic of a thin film transistor at a channel edge portion.

An edge portion 302 of a polysilicon layer 301 functioning as a channel layer is converted into a noncrystalline or fine crystalline area. Because a silicon semiconductor film at the channel edge portion 302 is in the fine crystalline or noncrystalline state, a current flowing there is extremely small, or a current does not flow there. Thus, even when a threshold voltage Vth at a channel central portion is different from that at a channel edge portion, performance of the entire thin film transistor film is little affected, so that display faults due to hump are prevented.

### CLAIM OF PRIORITY

The present application claims priority from Japanese Application JP 2006-339462 filed on Dec. 18, 2006, the content of which is hereby incorporated by reference into this application.

### BACKGROUND OF THE INVENTION

1. Field of the Invention

The present invention relates to a display device having a thin film transistor, and more specifically to a display device using a substrate comprising a thin film transistor with a channel formed from a low-temperature polysilicon semiconductor film and a method of manufacturing the display device.

2. Description of the Related Art

A thin film transistor comprising, for instance, a low-temperature polysilicon semiconductor film (LTPS-TFT) has the specific transistor characteristics that a threshold value Vth varies according to a place where a current flows, namely that a threshold value Vth at a central portion of a channel is different from that at an edge portion. This phenomenon occurs basically due to a film thickness distribution of a gate insulating film. In the LTPS-TFT, because a gate insulating film (mainly made of SiO₂) is formed by means of the CVD, the film thickness is largely influenced by shape of a polysilicon (p-Si) layer as an underlayer, and a film thickness in an edge portion (a step portion) is smaller than that in a flat portion because of the coverage characteristics in the film-forming process.

Because of the characteristics, an electric field applied to the channel varies according to a film thickness, which causes a variance in the threshold value Vth. A threshold value Vth in an edge portion (flat portion) of the channel is lower than that in a central portion of the channel (deplete direction). Thus, the specific characteristic, a hump occurs in the gate voltage—drain current characteristics (Vg-Id characteristic). Because the channel edge portion shows the deplete characteristic, faults such as leakage may occur in products.

Further, a thickness of a gate insulating film at a channel edge portion is different from a thickness of a gate insulating film at a channel central portion. In such a case, if the gate insulating film is used as a through film in an implantation process, this film thickness difference causes a variance in the effective dose amount. Accordingly, a threshold voltage Vth at a channel edge portion is different from that at a channel central portion (flat portion) as described above, resulting in faults in the characteristics.

To solve the problem described above, it can be considered to increase a dose amount to a channel (in the enhance direction). However, when the countermeasure described above is employed, a threshold voltage Vth at the main portions (a flat portion, and a central area) of the channel is further enhanced so that characteristic faults such as shortage of the ON-current will occur.

FIG. 28 is a view of an n-MOS LTPS thin film transistor manufactured according to the process flow in the conventional technique. FIG. 28A is a plan view, and FIG. 28B is a cross-sectional view taken along the line A-A′ in FIG. 28A. FIG. 29 is a view showing the gate voltage-drain voltage (Vg-Id) characteristics measured when the LTPS thin film transistor shown in FIG. 28 was used.

In FIG. 28, a gate electrode 202 is formed via a gate insulating film 205 on a polysilicon (p-Si) layer 201 which is a channel layer. An aluminum (Al) wiring 203 functioning as a source-drain electrode is provided above the polysilicon layer 201 at a position with the gate electrode 202 inbetween. The aluminum wiring 203 is connected via the contact hole 204 to the polysilicon layer 201.

In the thin film transistor having the configuration as described above, a voltage is applied to the aluminum wiring 203 functioning as a source-drain electrode. In FIG. 28, when a positive voltage is applied to the gate electrode 202, a drain current 206 and a drain current 207 flow in the direction of arrow in the polysilicon layer 201 as a channel.

Transistor characteristics on a gate electrode potential vary according to a difference between the drain current 206 flowing in the central portion of a channel and the drain current 207 flowing in the edge portion of a channel. The drain current 207 flowing in the channel edge portion flows in a portion 209 at which a film thickness of a gate insulating film 205 is smaller than that of the central portion 208, as shown in FIG. 28B. Therefore, in the transistor characteristics of this channel edge portion, an electric field applied to the channel in the channel edge portion is greater than that in the channel central portion.

Because of the transistor characteristics shown in FIG. 29, in the channel edge portion, the current flows out at a lower value of the gate voltage Vg, flowing only in the channel edge portion. Thus, a current increase proportional to the gate voltage Vg is not observed, the characteristics is limited to those indicated by a curve 211 (transistor characteristics of the channel edge portion).

On the other hand, in the channel central portion, a current flows out at the Vg of 0 V or more because of the effect of the channel implantation for controlling a threshold voltage Vth, and the characteristic is as shown by a curve 210 (transistor characteristics of the channel central portion) in which the drain current increases in proportion to the gate voltage Vg.

Therefore, the entire transistor exhibits the Vg-Id characteristic as shown by a curved line 212 obtained by superposing the curve 210 of the channel central portion on the curve 211 of the channel edge portion (transistor characteristics in the whole of the channel). A hump 213 caused by the transistor characteristics of a channel edge portion appears in the curved line 212 showing the Vg-Id characteristic in the whole transistor shown in FIG. 29, and shows the same characteristics as those of transistors in which the depletion occurs. The current of this hump 213 causes such faults as an incorrect circuit operation or leakage of a current.

The techniques of injecting impurities to the channel edge portion at a high concentration to intentionally shift the transistor characteristics of the edge portion in the enhance direction are disclosed in JP-A-2003-258262 and JP-A-2003-273362. JP-A-2003-258262 and JP-A-2003-273362 are different from each other in that a resist for the channel process is used as a mask for the implantation or a photo-lithographic process is added, but are identical in that impurities are injected to the channel edge portion to solve the problem described above.

### SUMMARY OF THE INVENTION

When a dose amount for channel implantation is increased, also characteristic of a central portion of a channel is shifted as an edge portion of the channel is shifted in the enhance direction; therefore faults, for instance, due to shortage of the ON-current occur. As a result, in a display device using the thin film transistor, it is difficult to obtain pixel display having uniform brightness in the entire display area. In the case of a thin film transistor based on the CMOS structure, because impurities having a different polarity are injected to the n-type transistor and the p-type transistor respectively, complicated processes such as selection of implantation for each type and a photographic process for area selection are required, which is one of the causes with which reduction of production cost of a display device is hindered.

An object of the present invention is to provide a display device capable of providing a high quality image display by suppressing faults in a thin film transistor such as an incorrect circuit operation or leakage due to humps caused by the transistor characteristic of a channel edge portion, and a method of manufacturing the display device.

To achieve the objects as described above, a display device according to the present invention uses a thin film transistor formed on an insulating substrate and having different crystallinity or active layers damaged differently at an edge portion and a central portion of a channel respectively. In the method of manufacturing the display device according to the present invention, at first a channel layer is formed (etched) using a resist as a mask, and then impurities such as argon (Ar) are implanted to a channel edge portion of the active layer using the resist. By implantation of the impurities such as Ar, damage is intentionally given to crystallinity at the channel edge portion to deteriorate the crystallinity there. Through the processes described above, the polysilicon (p-Si) is converted to a better crystalline silicon film, typically to an amorphous silicon (a-Si) film.

When the crystallinity at an edge portion of a channel is deteriorated as compared to that at a central portion of the channel, or the channel edge portion is converted to the amorphous state, mobility of the carrier becomes lower, which hiders smooth flow of a current. Because of the feature, even when a threshold voltage Vth at a central portion of a channel is different from that at an edge portion of the channel, because a current does not flow to the channel edge portion, such faults as depletion or generation of a leak current are suppressed.

Because a resist mask used for forming an active layer of a channel is also used as a mask for implantation of impurities, it is not necessary to add a photolithographic process, and what is required is only addition of an implantation process for deteriorating the crystallinity at the channel edge portion. Furthermore, it is not necessary to control a threshold voltage Vth at the channel edge portion through implantation of impurities, and therefore. Even when the technique is applied to the CMOS structure, it is not necessary to add the implantation process nor the photographic process, and the desired effect can be obtained only by adding the impurities implantation process for deteriorating the crystallinity.

Since a current does not flows in the channel edge portion, an implantation rate for controlling the threshold voltage Vth can be decided only according to the characteristic of the central portion of the channel. Thus, unlike the conventional technique, it is not necessary to adjust a dose amount for channel implantation according to the channel edge portion where depletion of the threshold voltage Vth occurs, and the dose amount can be reduced. Furthermore, because a threshold voltage at the channel central portion can be optimized, ON-current drop can be prevented.

The present invention can be applied to a liquid crystal display device, an organic EL display device, and other display devices based on various principles for image display.

### BRIEF DESCRIPTION OF THE DRAWINGS

FIG. 1 is a view illustrating a manufacturing process for an n-MOS top gate thin film transistor according to the present invention;

FIG. 2 is a view following FIG. 1 and illustrating a manufacturing process for an n-MOS top gate thin film transistor according to the present invention;

FIG. 3 is a view following FIG. 2 and illustrating the manufacturing process for an n-MOS top gate thin film transistor according to the present invention;

FIG. 4 is a view following FIG. 3 and illustrating the manufacturing process for an n-MOS top gate thin film transistor according to the present invention;

FIG. 5 is a view following FIG. 4 and illustrating the manufacturing process for an n-MOS top gate thin film transistor according to the present invention;

FIG. 6 is a view following FIG. 5 and illustrating the manufacturing process for an n-MOS top gate thin film transistor according to the present invention;

FIG. 7 is a view following FIG. 6 and illustrating the manufacturing process for an n-MOS top gate thin film transistor according to the present invention;

FIG. 8 is a view illustrating FIG. 7 and illustrating the manufacturing process for an n-MOS top gate thin film transistor according to the present invention;

FIG. 9 is a view following FIG. 8 and illustrating the manufacturing process for an n-MOS top gate thin film transistor according to the present invention;

FIG. 10 is a view following FIG. 9 and illustrating the manufacturing process for an n-MOS top gate thin film transistor according to the present invention;

FIG. 11 is a view following FIG. 10 and illustrating the manufacturing process for an n-MOS top gate thin film transistor according to the present invention;

FIG. 12 is a view following FIG. 11 and illustrating the manufacturing process for an n-MOS top gate thin film transistor according to the present invention;

FIG. 13 is a view following FIG. 12 and illustrating the manufacturing process for an n-MOS top gate thin film transistor according to the present invention;

FIG. 14 is a view following FIG. 13 and illustrating the manufacturing process for an n-MOS top gate thin film transistor according to the present invention;

FIG. 15 is a view following FIG. 14 and illustrating the manufacturing process for an n-MOS top gate thin film transistor according to the present invention;

FIG. 16 is a view following FIG. 15 and illustrating the manufacturing process for an n-MOS top gate thin film transistor according to the present invention;

FIG. 17 is a view following FIG. 16 and illustrating the manufacturing process for an n-MOS top gate thin film transistor according to the present invention;

FIG. 18 is a view following FIG. 17 and illustrating the manufacturing process for an n-MOS top gate thin film transistor according to the present invention;

FIG. 19 is a view following FIG. 18 and illustrating the manufacturing process for an n-MOS top gate thin film transistor according to the present invention;

FIG. 20 is a view following FIG. 19 and illustrating the manufacturing process for an n-MOS top gate thin film transistor according to the present invention;

FIG. 21 is a view following FIG. 20 and illustrating the manufacturing process for an n-MOS top gate thin film transistor according to the present invention;

FIG. 22 is a view following FIG. 21 and illustrating the manufacturing process for an n-MOS top gate thin film transistor according to the present invention;

FIG. 23 is a view following FIG. 22 and illustrating the manufacturing process for an n-MOS top gate thin film transistor according to the present invention;

FIG. 24 is a view following FIG. 23 and illustrating the manufacturing process for an n-MOS top gate thin film transistor according to the present invention;

FIG. 25 is a view following FIG. 24 and illustrating the manufacturing process for an n-MOS top gate thin film transistor according to the present invention;

FIG. 26 is a view illustrating an n-MOS LTPS thin film transistor manufactured according to the process flow of the present invention;

FIG. 27 is a view showing the gate voltage-drain voltage (Vg-Id) characteristics measured when the LTPS thin film transistor shown in FIG. 26 is used;

FIG. 28 is a view an n-MOS LTPS thin film transistor manufactured according to the process flow in the conventional technique; and

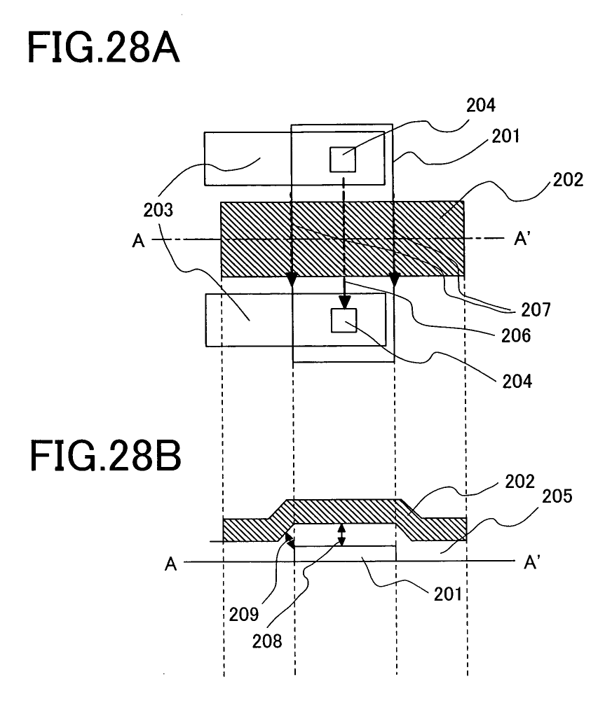

FIG. 29 is a view showing the gate voltage-drain voltage (Vg-Id) characteristics measured by the LTPS thin film transistor shown in FIG. 28.

### DETAILED DESCRIPTION OF THE PREFERRED EMBODIMENTS

A display device according to the present invention is described below with reference to examples of the manufacturing processes. Also a structure of the display device will be understood from description of the manufacturing process.

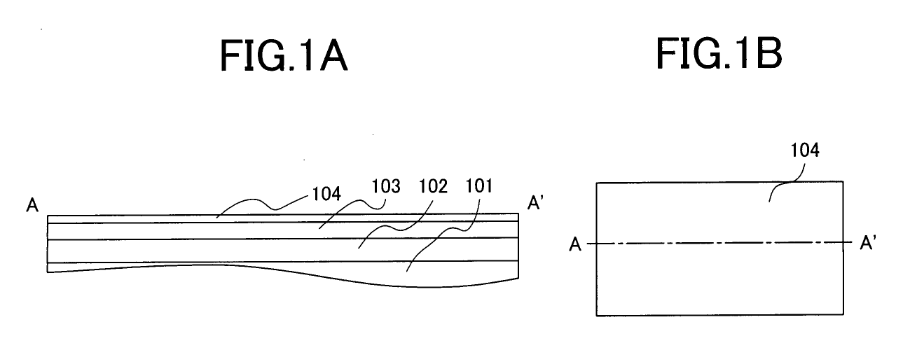

FIG. 1 to FIG. 25 are views each illustrating a flow of processes for manufacturing an n-MOS top gate thin film transistor according to the present invention, and shows a cross-sectional structure (a) and a plan view (b) of two types of transistors with the physical arrangement turned by 90 degrees. The cross-sectional view is taken along the line A-A′ in the plan view.

In FIG. 1, an SiN (silicon nitride) layer 102, an SiO₂ (silicon oxide) layer 103, and an amorphous silicon (a-Si) layer 104 are formed on a glass substrate 101 by a plasma CVD. Hydrogen atoms in the amorphous silicon (a-Si) layer 104 are desorbed by a thermal process. The SiN (silicon nitride) layer 102 and the SiO₂ silicon 103 are underlayers.

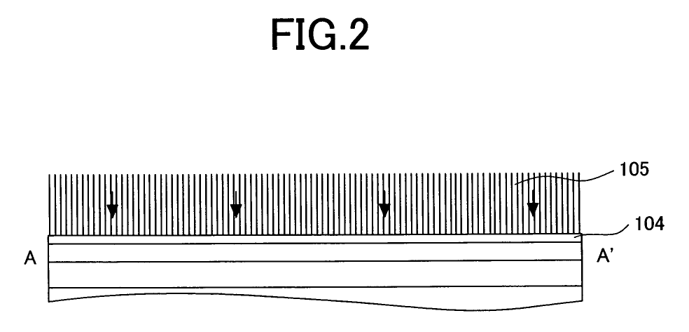

In FIG. 2, the amorphous silicon (a-Si) layer 104 is converted to a polycrystalline substance by irradiating the layer 104 with an excimer laser beam 105. The average particle diameter is about 2 μm (in the range from 1 to 3 μm).

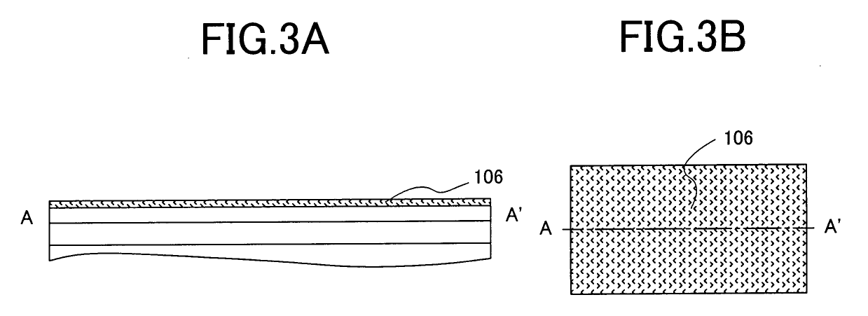

In FIG. 3, a polysilicon (p-Si) layer 106 is formed.

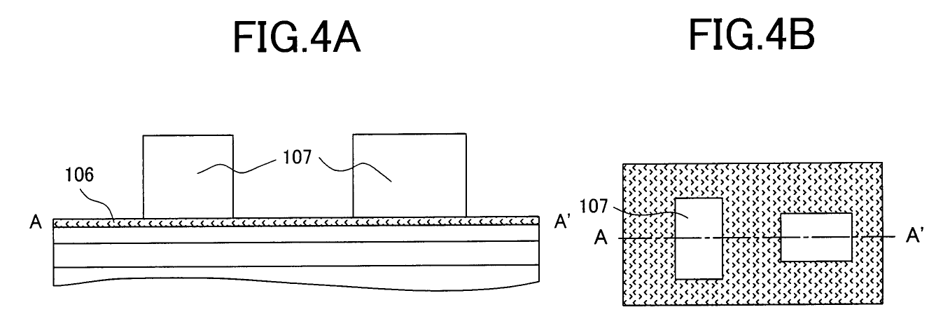

In FIG. 4, a photolithographic process is performed to the polysilicon (p-Si) layer 106 to provide a photoresist 107.

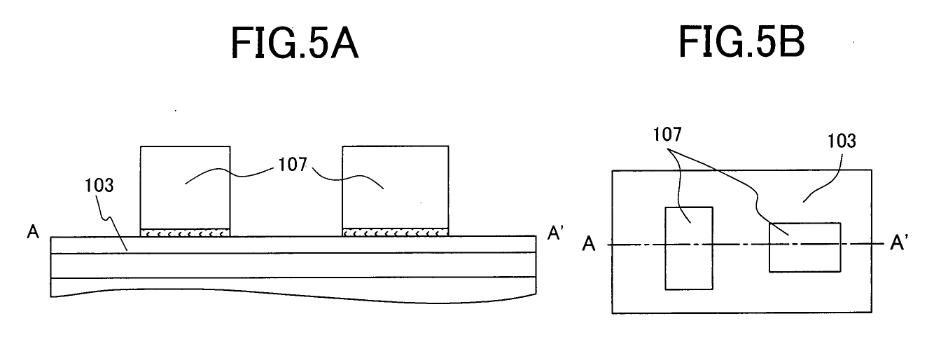

In FIG. 5, the polysilicon (p-Si) layer 106 is formed into an island-shaped state by dry-etching.

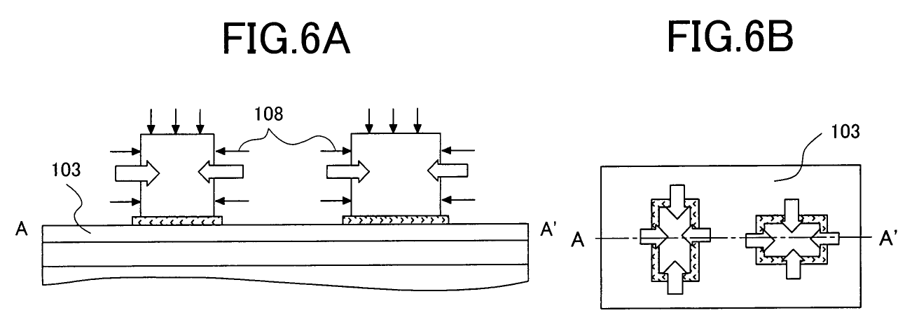

In FIG. 6, after the dry-etching is finished, an ashing process (108) or the like is performed to contract (set back) the photoresist 107 to expose an edge portion of the polysilicon layer.

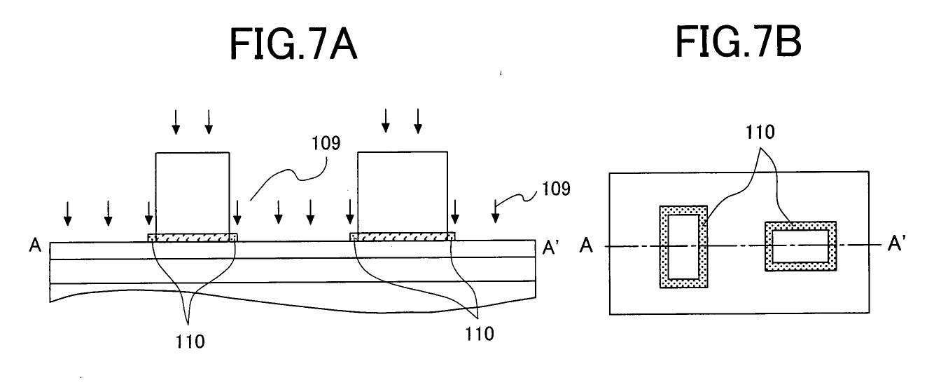

In FIG. 7, after the photoresist is contracted, the crystal is damaged at an exposed edge portion 110 by using argon implantation 109. This allows the polysilicon to be converted to a fine crystalline or amorphous state. The average particle diameter when the polysilicon is converted into the fine crystalline state is in the range from several tens nm to several hundreds nm.

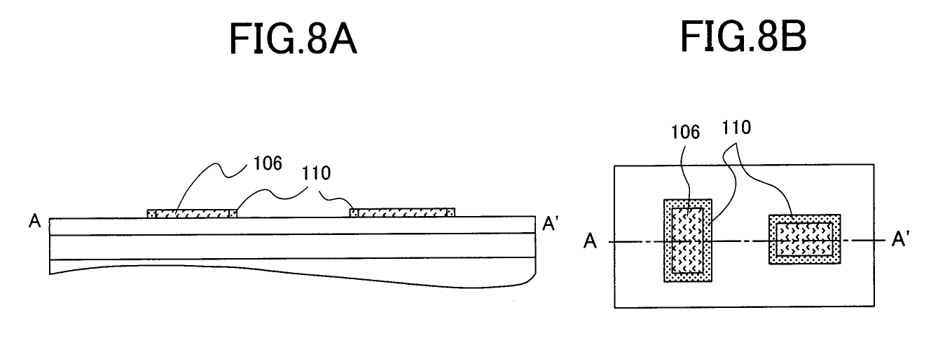

In FIG. 8, the pattern of the polysilicon layer processed after the photoresist is removed is such that the central portion remains as the polysilicon (p-Si) layer 106, while a fine crystalline or noncrystalline area is formed in the edge portion 110 by implanting impurities to give damage thereto. A width of the fine crystalline or noncrystalline is about 1 μm to the inner side from an edge of the island-like pattern.

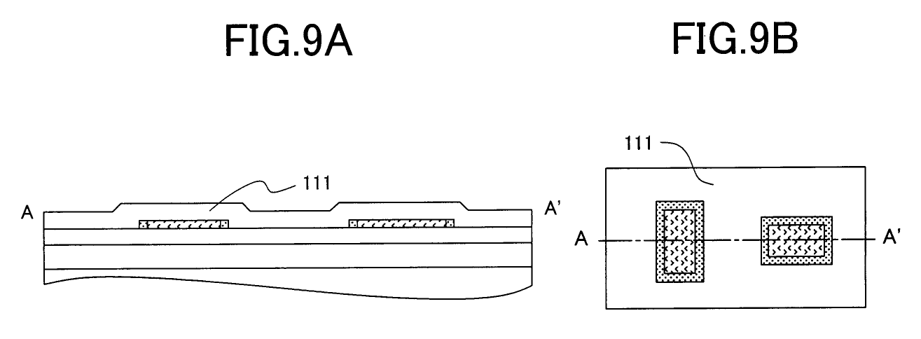

In FIG. 9, an SiO₂ film 111 is formed as a gate insulating film by the plasma CVD method on the island-shaped silicon semiconductor film (namely the polysilicon (p-Si) layer 106 and the edge portion 110).

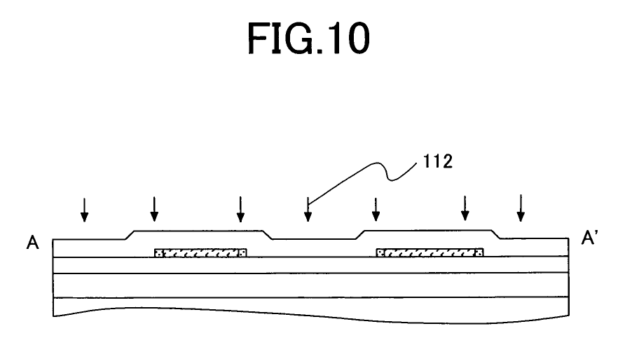

In FIG. 10, channel implantation (B′) 112 for controlling a threshold voltage Vth is performed.

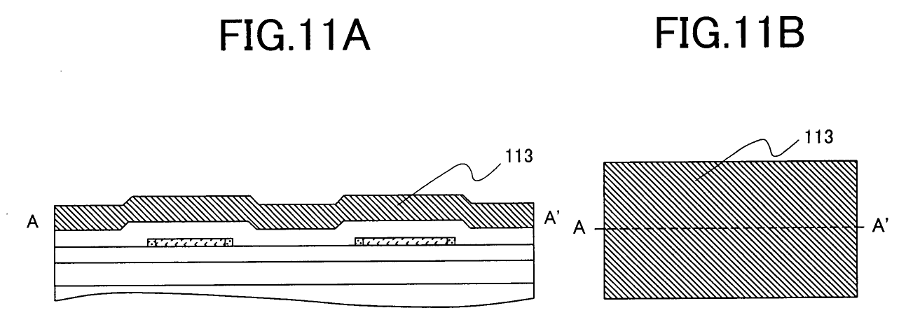

In FIG. 11, a gate metal layer 113 is formed, on which gate wiring and a capacitive line are provided.

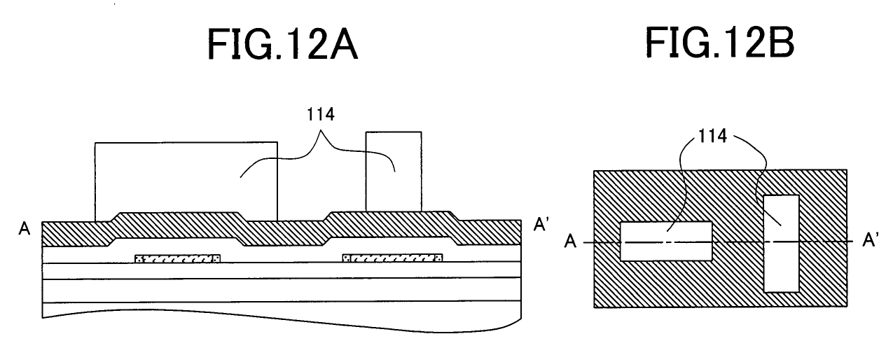

In FIG. 12, a photoresist 114 is formed by a photographic process.

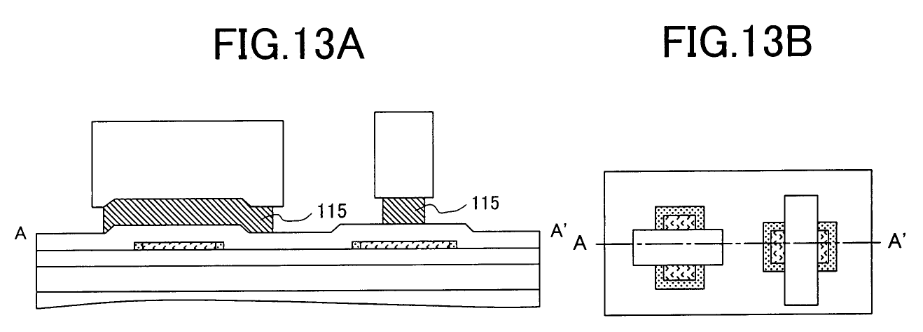

In FIG. 13, the gate metal 113 is subjected to etching to form a gate metal layer 115. In this step, a dimension of the formed gate metal 115 is made smaller as compared to the photoresist 114 by performing side etching.

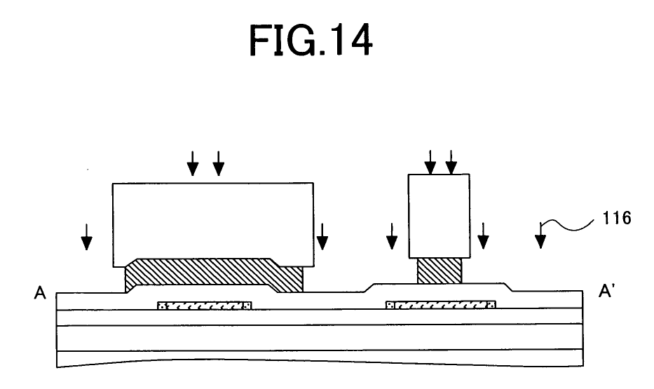

In FIG. 14, implantation for preparing a source-drain area (P⁺) 116 is carried out.

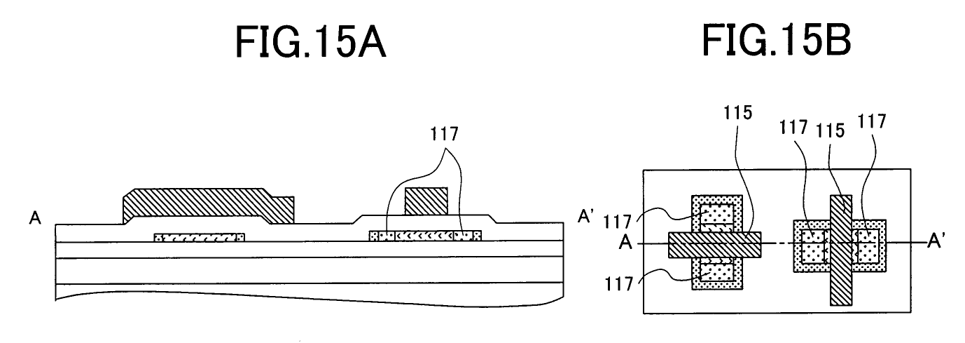

In FIG. 15, a source-drain electrode 117 is formed.

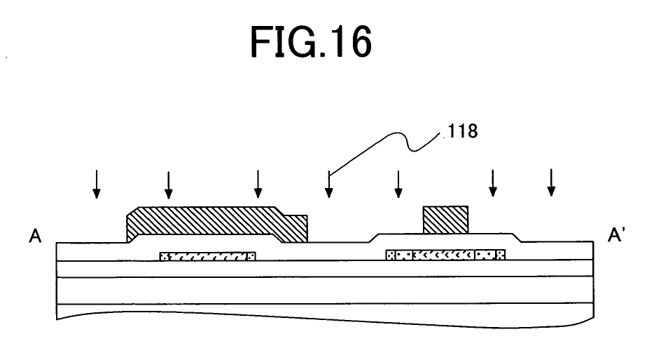

In FIG. 16, low density P⁺ 118 is implanted using the process gate metal layer 115 as a mask to prepare an LDD (lightly-doped drain) area.

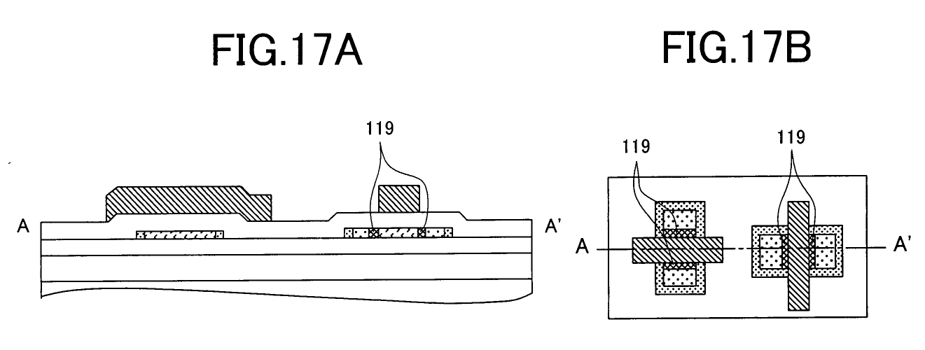

In FIG. 17, an LDD area 119 is formed.

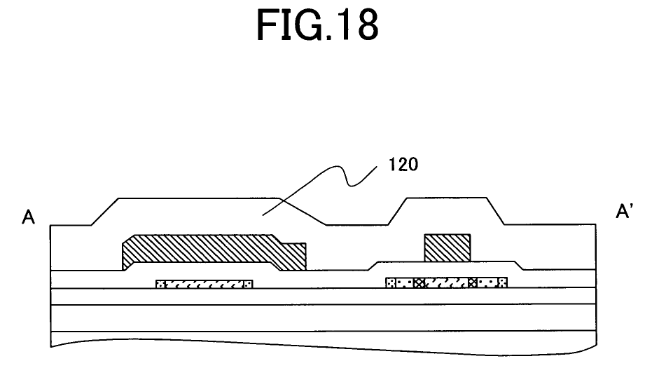

In FIG. 18, an interlayer insulating film 120 is formed. Annealing is then performed to activate implanted impurities.

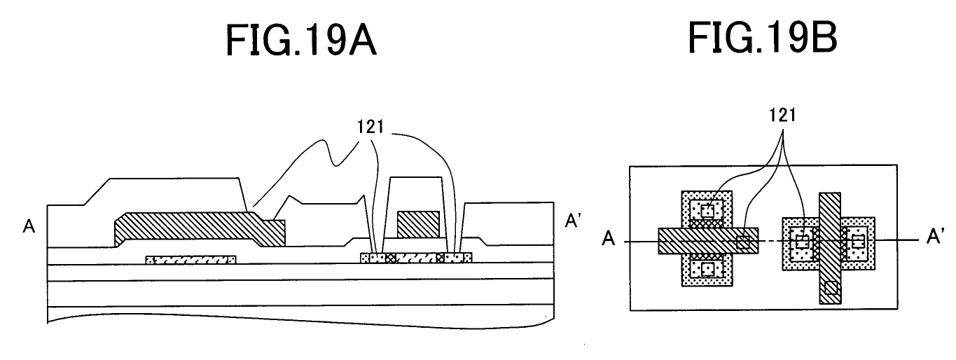

In FIG. 19, a contact hole 121 is subjected to photo-etching.

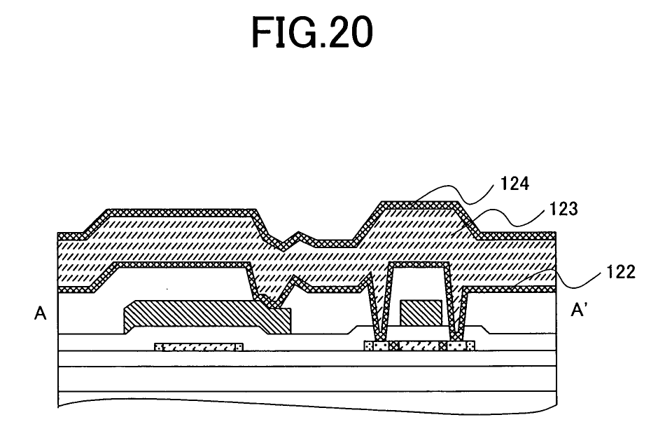

In FIG. 20, source-drain wiring (a barrier layer 122, an AL layer 123, and a cap layer 124) is formed.

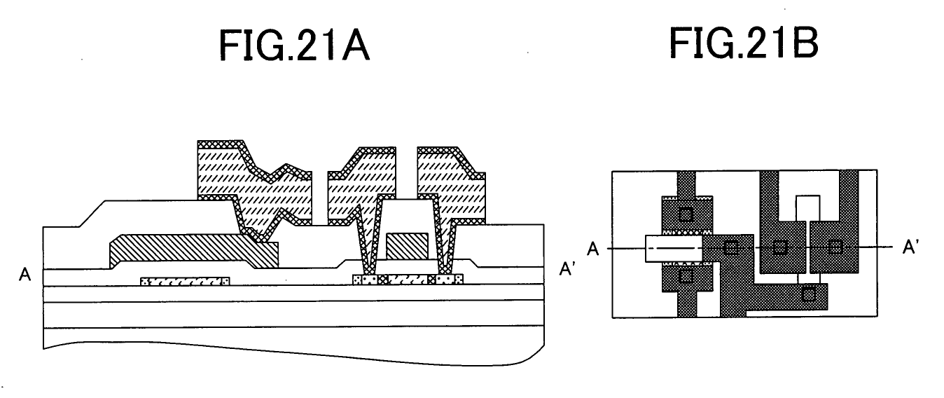

In FIG. 21, source-drain wiring (a barrier layer 122, an AL layer 123, and a cap layer 124) is subjected to photo-etching.

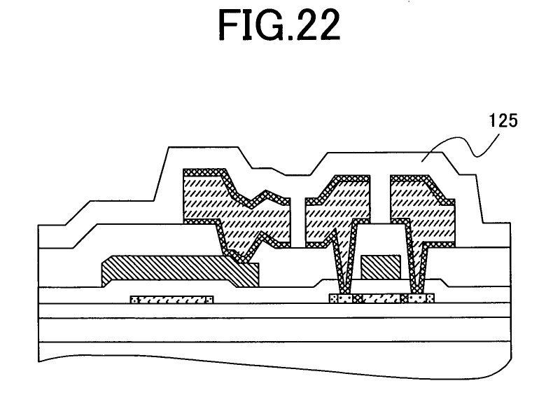

In FIG. 22, a passivation film 125 is formed by the plasma CVD method. Then a hydrogen-terminating process is performed to complete a thin film transistor.

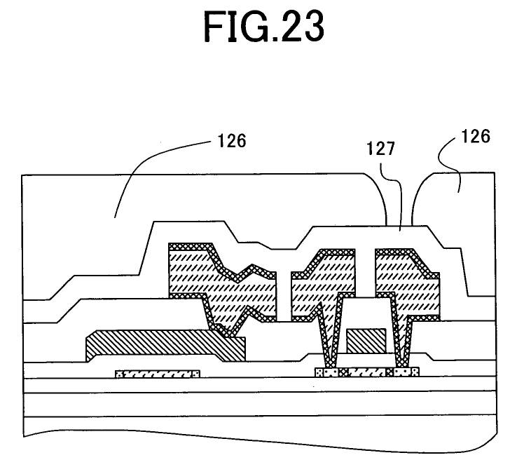

In FIG. 23, a flattening film 126 is applied for improving the display performance, and a contact hole 127 is formed by photo-etching.

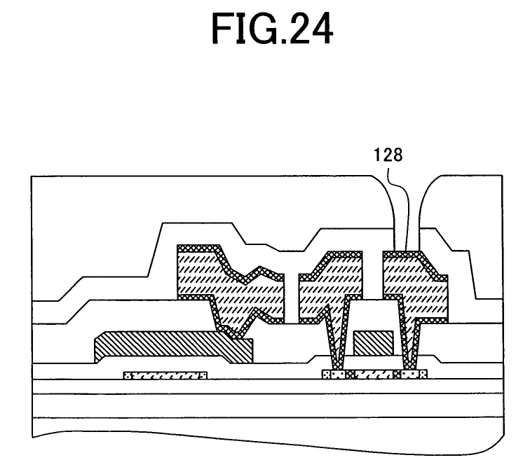

In FIG. 24, the passivation film 125 is formed by dry etching as an area for forming the contact hole 127, and a control hole 128 for contact with an ITO and an opening for PAD are formed therein.

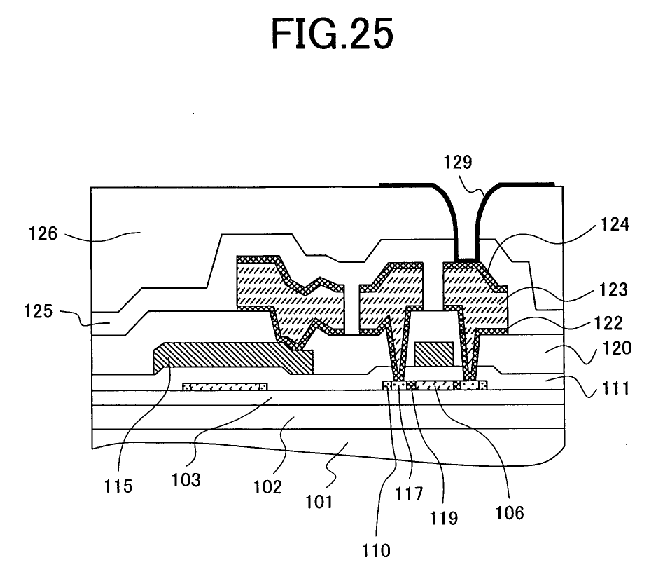

In FIG. 25, an ITO 129 functioning as a pixel electrode is formed and processed.

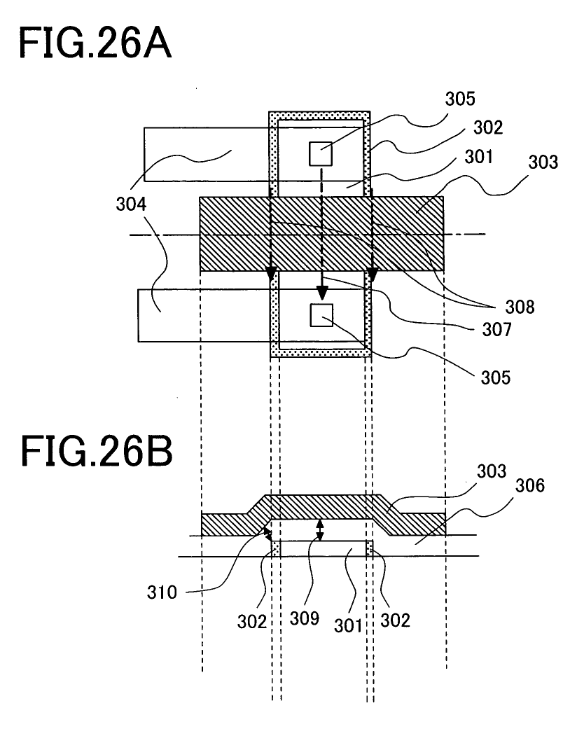

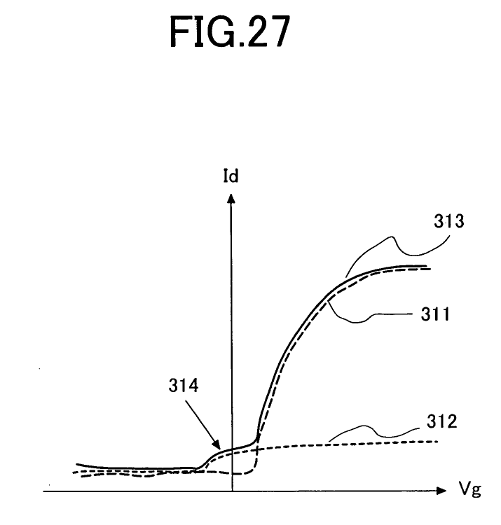

FIG. 26 is a view for illustrating an LTPS thin film transistor (n-MOS type) manufacturing according to the process flow of the present invention, and FIG. 26A is a plan view, while FIG. 26B us a cross-sectional view taken along the line A-A′ in FIG. 26A. FIG. 27 is a view showing the gate voltage-drain current (Vg-Id) characteristic measured when the LTPS thin film transistor shown in FIG. 26 is used.

In FIG. 26, a gate electrode 303 is formed via a gate insulating film 306 on a polysilicon (p-Si) layer 301 which is a channel layer. AN aluminum (Al) wiring 304 functioning as a source-grain electrode is provided on the polysilicon (p-Si) layer at a position with the gate electrode inbetween, and the aluminum wiring 304 is connected via a contact hole 305 to the polysilicon (p-Si) layer 301.

The edge portion 302 of the polysilicon (p-Si) layer 301 as a channel layer functions as the noncrystalline or fine crystalline area. Because a thickness 310 of the gate insulating film 306 at the edge section 302 is smaller as compared to a thickness 319 of the gate insulating section 306 at a channel central portion, the threshold value Vth is low.

A gate voltage (Vth) at which a current flows out is lower for a drain current 308 flowing in the edge section 302 as compared to the drain current 307 flowing in a central portion of the channel since the gate insulating film 306 is thinner.

However, because the silicon semiconductor at the edge portion 302 is in the fine crystalline or a noncrystalline state, the drain current 308 flowing in the edge portion 302 can be made extremely smaller than the drain current 307 flowing in the central portion of the channel. Further it is also possible to substantially eliminate the current. With the configuration as described above, mobility at a central portion of the channel can be made larger an order of magnitude or more than that at an edge portion of the channel.

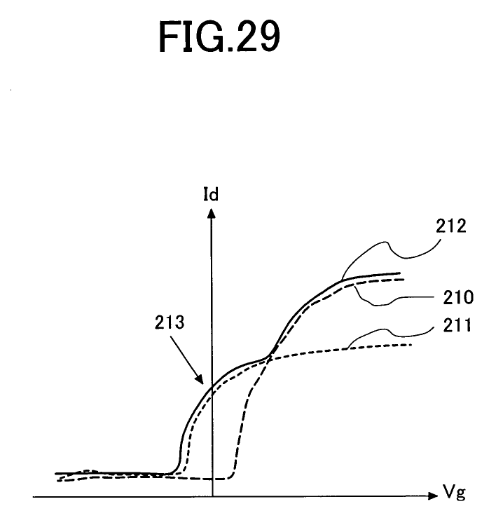

In FIG. 27, a curve 311 represents the Vg-Id characteristic of a central portion of a channel, while a curve 312 represents the Vg-Id characteristic of an edge portion of the channel. A drain current in the channel edge portion flows out at a lower gate voltage, but an amount of the current is smaller. Therefore, even when a threshold voltage Vth at a central portion of a channel is different from that at an edge portion of the channel, the curve 313 representing the general characteristic of the entire transistor is little affected, so that the hump as shown in FIG. 29 does not occur.

Because of the features as described above, the trouble due to the depletion does not occur. In addition, because an amount of implanted impurities for forming a channel to control a threshold value Vth can be adjusted by attention to only the characteristic at a central portion of the channel, and a shortage of a current due to shift of a threshold value Vth for a thin film transistor does not occur at the channel central portion. Therefore, with the present invention, it is possible to provide a display device in which such faults as malfunctions of a circuit or current leakage due to hump caused by the transistor characteristic of the channel edge portion are suppressed and a high quality image display is provided.

What is claimed is:

1. A display device comprising:
a thin film transistor formed on an insulating substrate;
wherein, in the thin film transistor, an active layer for forming a channel is a silicon semiconductor film layer;
the channel has a channel central portion and a channel edge portion which is an edge portion in a direction of a channel width; and
crystallinity of the silicon semiconductor film layer at the channel central portion is different from that at the channel edge portion.

2. The display device according to claim 1,
wherein carrier mobility at the channel central portion is different an order of magnitude or more than from that in the channel edge portion.

3. The display device according to claim 1,
wherein particle diameters of polysilicon at the channel central portion is larger than that at the channel edge portion.

4. The display device according to claim 3,
wherein an average particle diameter of polysilicon at the channel central portion is in the range from 1 μm to about 3 μm, and an average particle diameter of polysilicon at the channel edge portion is in the range from several tens μm to several hundreds μm.

5. The display device according to claim 1,
wherein the channel central portion is a polysilicon film and the channel edge portion is an amorphous silicon film.

6. The display device according to claim 1,
wherein crystallinity defects at the channel central portion are different from those at the channel edge portion.

7. A display device having a thin film transistor formed on an insulating substrate,
wherein, in the thin film transistor, an active layer for forming a channel is a silicon semiconductor film layer;
a gate insulating film is formed to cover the active layer, and a gate electrode is formed on the gate insulating film;
the channel has a channel central portion and a channel edge portion which is an edge portion in a direction of a channel width;
crystallinity of the silicon semiconductor film layer at the channel central portion is different from that at the channel edge portion; and
a thickness of the gate insulating film at the channel central portion is smaller than that at the channel edge portion.

8. The display device according to claim 7,
wherein carrier mobility at the channel central portion is different an order of magnitude or more than from that at the channel edge portion.

9. The display device according to claim 7,
wherein particle diameters of polysilicon at the channel central portion are larger than those at the channel edge portion.

10. A method of manufacturing a display device having a thin film transistor formed on the insulating layer, the method comprising the steps of:
forming a preparing an insulating substrate;
forming a polysilicon film on the insulating substrate;
applying a photosensitive resist film for forming an island-shaped active layer to form a channel of the thin film transistor, exposing and developing the photosensitive resist to form a resist film having an island-shaped layer pattern;
etching the polysilicon film, by using the resist film having an island-shaped active layer pattern as a mask, to form the island-shaped active layer;
subjecting the resist film used in forming the island-shaped active layer to ashing to contract the side edge for setting back and expose the island-shaped active layer at the channel edge portion; and
implanting impurities in the exposed portion of the island-shaped active layer.

11. The method of manufacturing a display device,
wherein the impurity is argon.

12. The method of manufacturing a display device according to claim 10,
wherein the exposed portion of the island-shaped active layer is converted into a fine crystalline state by implanting the impurity.

13. The method of manufacturing a display device according to claim 10,
wherein the exposed portion of the island-shaped active layer is converted into an amorphous state.
